(19) United States
(12) Patent Application Publication
(10) Pub. No.: US 2011/0024919 A1
(43) Pub. Date: Feb. 3, 2011

(54) WIRING SUBSTRATE FOR A SEMICONDUCTOR CHIP AND SEMICONDUCTOR PACKAGE HAVING THE WIRING SUBSTRATE

(76) Inventors: Tae-Gyu Kang, Asan-si (KR); Wha-Su Sin, Cheonan-si (KR); Jun-Soo Han, Cheonan-si (KR)

Correspondence Address: Intellectual Property Team, SAMSUNG SEMICONDUCTOR,;SAMSUNG ELECTRONIC CO., LTD.,, San #16, Banwol-dong, Hwaseong-si, Gyeonggi-do, 445-701, KR

(21) Appl. No.: 12/841,310

(22) Filed: Jul. 22, 2010

(30) Foreign Application Priority Data
Jul. 31, 2009 (KR) 10-2009-0070537

(51) Int. Cl. H01L 23/488; H05K 1/18

(52) U.S. Cl. 257/782; 174/261; 257/E23.023

(57) ABSTRACT

A wiring substrate for a semiconductor chip includes a substrate having a first face and a second face opposite to the first face. The substrate has a window from the first face to the second face that exposes chip pads of a semiconductor chip adherable to the first face. A first bonding pad is arranged on the second face along a side portion of the window. The first bonding pad is connected to a bonding wire drawn from the chip pad through the window at a predetermined angle with respect to the side portion. A second bonding pad is adjacent to the first bonding pad on the second face. The second bonding pad includes an end portion having an inclined side portion at an angle corresponding to the drawn angle of the first bonding wire for avoiding an overlap of the second bonding pad with the first bonding wire.

### CROSS-REFERENCE TO RELATED APPLICATION

This application claims under 35 U.S.C. §119 priority to and the benefit of Korean Patent Application No. 2009-70537, filed on Jul. 31, 2009 in the Korean Intellectual Property Office (KIPO), the entire content of which is incorporated by reference herein.

### BACKGROUND

1. Technical Field

The present disclosure relates to substrates, and, more particularly, to wiring substrates for mounting a semiconductor chip thereon where the semiconductor chip is electrically connected to the wiring substrate by a plurality of bonding wires, and a semiconductor package having the same.

2. Discussion of the Related Art

Typically, semiconductor devices are manufactured by various fabrication processes for forming electrical circuits having electrical elements on a semiconductor substrate. When the semiconductor device, e.g., a semiconductor chip, is electrically connected to a mounting substrate, and the semiconductor chip is sealed to be protected from the outside. The semiconductor package including the semiconductor chip mounted on the mounting substrate dissipates heat from the semiconductor chip to the outside through cooling functions thereof, such as cooling fins, and the like.

In the semiconductor package, the semiconductor chip may be electrically connected to the mounting substrate by a plurality of bonding wires.

As the number of input/output signal lines for the semiconductor chip is increase, dimensions of the wiring substrate for mounting the semiconductor chip and line widths between the wiring patterns would decrease.

When semiconductor chips are adhered to wiring substrates such that chip pads of the semiconductor chips are arranged to be offset to bonding pads of the wiring substrates, bonding wires electrically connecting the chips to the bonding pads may make undesired contact with an adjacent bonding pad.

### SUMMARY

Exemplary embodiments of the present inventive concept provide a wiring substrate for a semiconductor chip that includes a bonding pad structure capable of avoiding interference with an adjacent bonding wire.

Exemplary embodiments also provide a semiconductor package that includes the wiring substrate.

According to an exemplary embodiment, a wiring substrate for a semiconductor chip, includes a substrate having a first face and a second face opposite to the first face, the substrate having a window from the first face to the second face that exposes chip pads of a semiconductor chip adherable to the first face. A first bonding pad is arranged on the second face along a side portion of the window, the first bonding pad connected to a bonding wire that is drawn from the chip pad through the window at a predetermined angle with respect to the side portion of the window. A second bonding pad is adjacent to the first bonding pad on the second face, the second bonding pad including an end portion having an inclined side portion of a predetermined angle with respect to the side portion of the window corresponding to the drawn angle of the bonding wire for avoiding an overlap of the second bonding pad with the first bonding wire.

The inclined side portion of the end portion of the second bonding pad may extend at substantially the same angle as the drawn angle of the bonding wire.

The end portion of the second bonding pad may have an angle of the inclined side portion that ranges from about 10° to about 50° from the side portion of the window.

The width of the end portion of the second bonding pad may decrease gradually toward the window.

The second bonding pad may include a pad body connected to a second bonding wire, the pad body having a first width and the end portion of the second bonding pad having a second width smaller than the first width.

The pad body of the second bonding pad may have a modified rectangular shape characterized by the end portion of the second bonding pad having a trapezoidal shape.

The first and second bonding pads may extend substantially perpendicular to the side portion of the window.

A plurality of the first and second bonding pads may be arranged to alternate with one another, a first bonding pad being spaced further from the side portion of the window than a second bonding pad spaced from the side portion.

According to an exemplary embodiment a semiconductor package includes a substrate having a first face and a second face opposite to the first face and having a window from the first face to the second face. A semiconductor chip is adhered to the first face of the substrate and has semiconductor chip pads exposed through the window. A first bonding pad is arranged on the second face along a side portion of the window. A second bonding pad is adjacent to the first bonding pad on the second face, the second bonding pad including an end portion having an inclined side portion of a predetermined angle with respect to the side portion of the window. A bonding wire is drawn from the chip pad through the window and is connected to the first bonding pad at a predetermined angle with respect to the side portion of the window corresponding to the inclined side portion of the second bonding pad for avoiding an overlap of the second bonding pad with the bonding wire.

The second bonding pad may include a pad body connected to a second bonding wire, the pad body having a first width, the end portion of the second bonding pad having a second width smaller than the first width, and the chip pad of the semiconductor chip having a third width smaller than the first width.

The inclined side portion of the end portion of the second bonding pad may extend at substantially the same angle as a drawn angle of the bonding wire.

The end portion of the second bonding pad may have an angle of the inclined side portion ranging from about 10° to about 50° from the side portion of the window.

The width of the end portion of the second bonding pad may decrease gradually toward the window.

The second bonding pad may include a pad body connected to a second bonding wire, the pad body oldie second bonding pad having a modified rectangular shape characterized by the end portion of the second bonding pad having a trapezoidal shape.

The first and second bonding pads may extend substantially perpendicular to the side portion of the window.

A plurality of the first and second bonding pads may be arranged to alternate with one another, and the first bonding pad may be arranged further from the side portion of the window than the second bonding pad is from the side portion of the window.

According to an exemplary embodiment a wiring interconnection apparatus for a semiconductor chip that adheres to a substrate, the substrate having a window from a substrate adhering surface to a bonding pad surface is provided. A plurality of chip pads is arranged on a surface of the semiconductor chip that adheres to the substrate adhering surface. A plurality of bonding pads is arranged substantially parallel on the bonding pad substrate surface. A plurality of bonding wires are provided, each bonding wire passing through the window and coupling a respective chip pad and bonding pad. Each bonding pad is shaped such that at least one bonding pad has an inclined edge substantially parallel to a bonding wire of an adjacent bonding pad.

The bonding pads may be substantially perpendicular to a side portion of the window.

At least one of the bonding wires may be oblique to the side portion of the window.

According to exemplary embodiments, a wiring substrate for a semiconductor chip includes adjacent first and second bonding pads on a substrate, the second bonding pad includes an end portion having an inclined side portion of a predetermined angle with respect to a side portion of the window corresponding to the drawn angle of a bonding wire connected to the first bonding pad, for avoiding an overlap with the first bonding wire

Accordingly, even though the first and second bonding pads are spaced apart from each other by a relatively small distance and the bonding wire is connected to the first bonding pad at a predetermined angle with respect to the side portion of the window, the second bonding pad may be prevented from overlapping with the first bonding wire. Thus, a contact failure between the second bonding pad and the bonding wire may be prevented.

### BRIEF DESCRIPTION OF THE DRAWINGS

Exemplary embodiments will be more clearly understood from the following detailed description taken in conjunction with the accompanying drawings.

FIG. 1 is a plan view illustrating a semiconductor package in accordance with an exemplary embodiment.

FIG. 2 is a cross-sectional view illustrating the semiconductor package of FIG. 1.

FIG. 3 is an enlarged plan view illustrating the “A” portion in FIG. 1.

FIG. 4 is a cross-sectional view taken along the IV-IV′ line in FIG. 3.

FIG. 5 is a plan view illustrating bonding pads of a semiconductor package in accordance with an exemplary embodiment.

FIG. 6 is a plan view illustrating a semiconductor package in accordance with an exemplary embodiment.

FIGS. 7, 8, 9 and 10 are cross-sectional views illustrating a method of manufacturing the wiring substrate for the semiconductor chip of FIG. 1.

FIG. 11 is an enlarged view illustrating the wiring substrate for the semiconductor chip of FIG. 10.

### DETAILED DESCRIPTION OF EXEMPLARY EMBODIMENTS

Exemplary embodiments of the present inventive concept will be described more fully hereinafter with reference to the accompanying drawings, in which exemplary embodiments are shown. Like numerals refer to like elements throughout.

It will be understood that when an element or layer is referred to as being “on,” “connected to” or “coupled to” another element or layer, it can be directly on, connected or coupled to the other element or layer or intervening elements or layers may be present.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the exemplary embodiments.

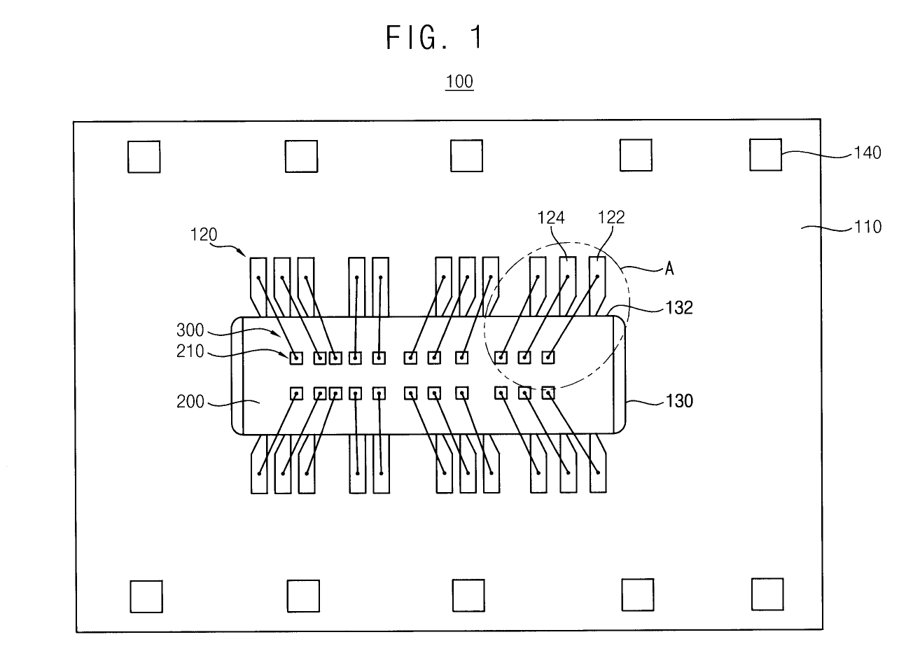

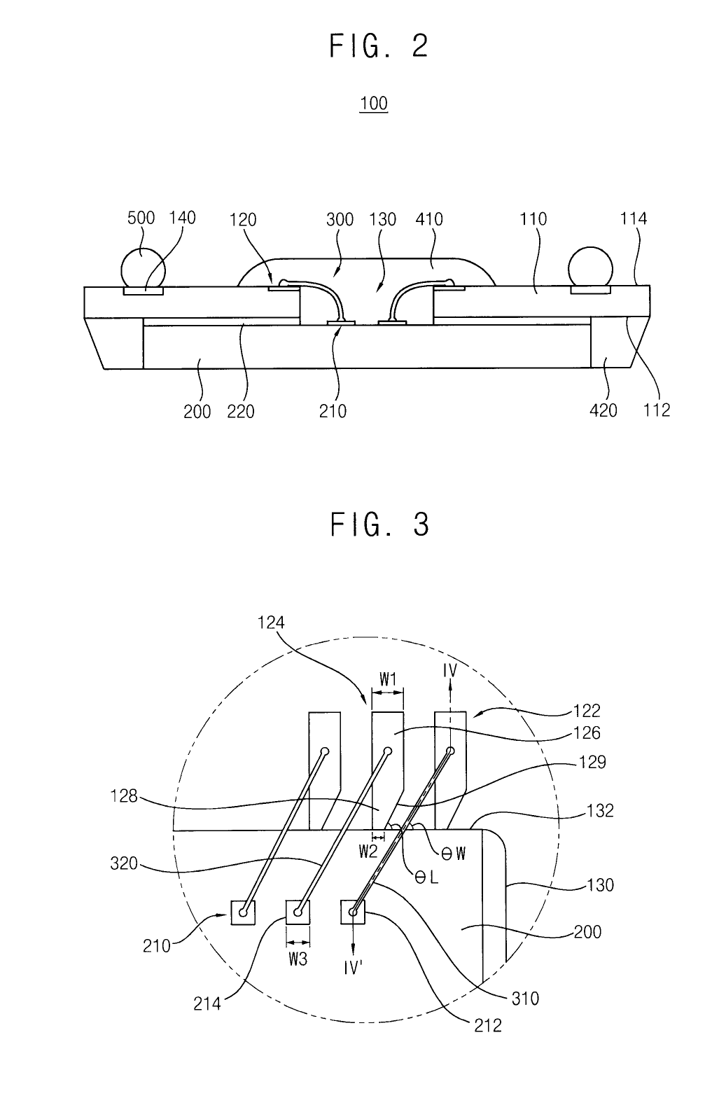

FIG. 1 is a plan view illustrating a semiconductor package in accordance with an exemplary embodiment. FIG. 2 is a cross-sectional view illustrating the semiconductor package of FIG. 1.

Referring to FIGS. 1 and 2, a semiconductor package 100 includes a substrate 110, a semiconductor chip 200 mounted on the substrate 110, and a plurality of bonding wires 300 electrically connecting the semiconductor chip to the substrate 110.

A wiring substrate for a semiconductor chip according to an exemplary embodiment may include the substrate 100 for mounting the semiconductor chip 200 and first and second bonding pads 122, 124 formed on the substrate 110. The substrate 110 may have a first face 112 and a second face 114 opposite to the first face 112. In an exemplary embodiment the substrate 110 may be a printed circuit board (PCB).

A window 130 may be formed in the middle region of the substrate 110. The window 130 may penetrate the substrate 110. In an exemplary embodiment the window 130 may have a substantially rectangular shape. Accordingly, chip pads 210 of the semiconductor chip 200 may be exposed through the window 130.

The semiconductor chip 200 may adhere to the first face 112 of the substrate 110. The semiconductor chip 200 may adhere to the substrate 110 via an adhesive film 220. A plurality of the chip pads 210 may be formed on an active surface of the semiconductor chip 200. The chip pads 210 of the semiconductor chip 200 on the substrate 110 may be exposed through the window 130. Although it is not illustrated in the figures, at least one semiconductor chip may be additionally formed on the semiconductor chip 200.

In an exemplary embodiment, the semiconductor chip 200 may include a plurality of the circuit elements. The circuit elements may include a plurality of memory devices. Examples of the memory devices may be a volatile memory device and a non-volatile memory device. Examples of the volatile memory device may be DRAM, SRAM, and the like. Examples of the non-volatile memory device may be EPROM, EEPROM. Flash EEPROM, and the like.

A plurality of bonding pads 120 may be arranged on the second face 114 of the substrate 110 along a side portion 132 of the window 130. The bonding pads 120 may be connected to respective chip pads 210 of the semiconductor chip 200 by the bonding wires 300. The bonding wire 300 may be drawn from the chip pad 210 of the semiconductor chip 200 through the window 130 to be connected to the bonding pad 120 on the substrate 110.

In an exemplary embodiment, the bonding wire 300 may be connected to the bonding pad 120 at a predetermined angle with respect to the side portion 132 of the window 130. The second bonding pad 124 may include an end portion having an inclined side portion. The inclined side portion of the end portion may extend at a predetermined angle corresponding to the drawn angle of the bonding wire 300 that is connected to the first bonding pad 122 adjacent to the second bonding pad 124 for avoiding an overlap with the adjacent bonding wire 300.

In an exemplary embodiment, a plurality of solder ball pads 140 may be provided on the second face 114 of the substrate 100 along a peripheral region of the substrate 100. A solder ball 500 may be disposed on the solder ball pad 140, and the semiconductor package 100 may be mounted on a module substrate (not illustrated) via the solder balls 500 to provide a memory module (not illustrated).

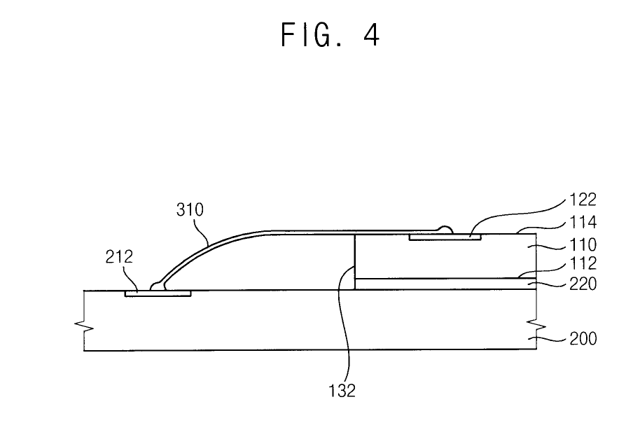

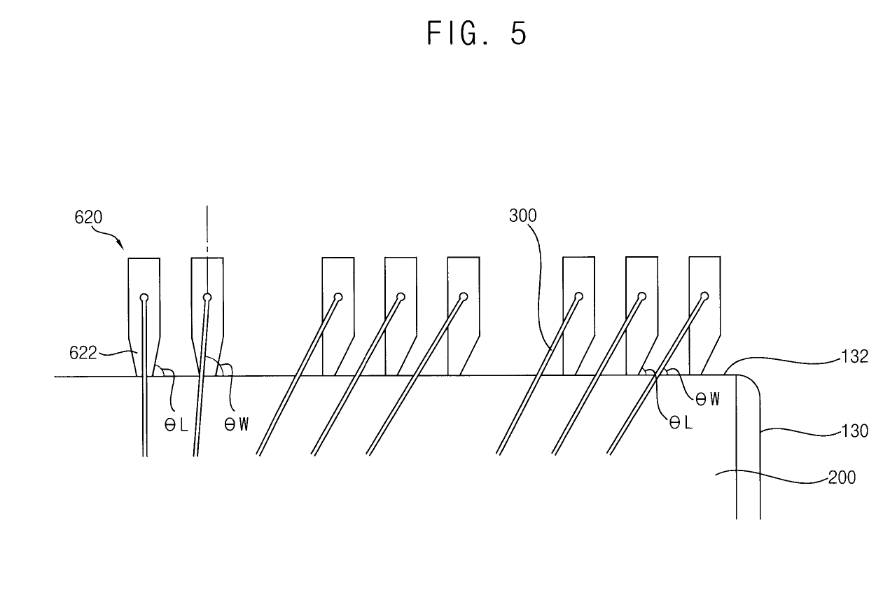

FIG. 3 is an enlarged plan view illustrating the “A” portion of FIG. 1. FIG. 4 is a cross-section view taken along the IV-IV′ line in FIG. 3.

Referring to FIGS. 3 and 4, the first bonding pad 122 and the second bonding pad 124 are arranged on the second face 114 of the substrate 110 along the side portion 132 of the window 130. The first and second chip pads 212, 214 are formed on the active surface of the semiconductor chip 200. The first and second chip pads 212, 214 are spaced apart from each other by a predetermined distance.

A first bonding wire 310 is drawn from the first chip pad 212 of the semiconductor chip 200 through the window 130 to be connected to the first bonding pad 122. A second bonding wire 320 is drawn from the second chip pad 214 of the semiconductor chip 200 through the window 130 to be connected to the second bonding pad 124.

In an exemplary embodiment, the first chip pad 212 of the semiconductor chip 200 may be arranged to be offset from an imaginary longitudinal line extending through the first bonding pad 122. The second chip pad 214 of the semiconductor chip 200 may be arranged to be offset from an imaginary longitudinal line extending through the second bonding pad 124.

In this case, the first bonding wire 310 may be connected to the first bonding pad 122 120 at a predetermined angle θW with respect to the side portion 132 of the window 130. The second bonding wire 320 may be connected to the second bonding pad 124 at a similar predetermined angle θW with respect to the side portion 132 of the window 130.

In an exemplary embodiment, the second bonding pad 124 may include an end portion 128 adjacent to the side portion 132, that is, the inner wall of the window 130. The end portion 128 may have an inclined side portion 129 of a predetermined angle θL. The inclined side portion 129 of the second bonding pad 124 may extend at a predetermined angle θL corresponding to the drawn angle θW of the first bonding wire 310 for avoiding an overlap with the first bonding wire 310 that is connected to the first bonding pad 122.

Accordingly, the second bonding pad 124 may be prevented from overlapping the first bonding wire 310 that is connected to the first bonding pad 122 at a predetermined angle with respect to the side portion 132 of the window 130. As such, the end portion 128 of the second bonding pad 124 adjacent to the first bonding pad 122 provides a pad structure capable of avoiding an overlap with the adjacent first bonding wire 310.

In an exemplary embodiment, the end portion 128 of the second bonding pad 124 may have an inclined side portion of an angle substantially the same as the drawn angle θW of the first bonding wire 310. In an exemplary embodiment, the end portion 128 of the second bonding pad 124 may have the inclined side portion ranging from about 10° to about 50°.

The second bonding pad 124 may include a pad body 126 connected to the second bonding wire 320. The pad body 126 of the second bonding pad 124 may have a first width W1 and the end portion of the second bonding pad 124 may have a second width W2 smaller than the first width W1. The width of the end portion 128 of the second bonding pad 124 may decrease gradually toward the window 130. The chip pad 210 of the semiconductor chip 200 may have a third width W3 smaller than the first width W1.

The pad bodies of the first and second bonding pads 122, 124 may have modified rectangular shapes. The pad body of first bonding pad 122 may extend substantially perpendicular to the side portion 132 of the window 130. The pad body 126 of the second bonding pad 124 may extend substantially perpendicular to the side portion 132 of the window 130.

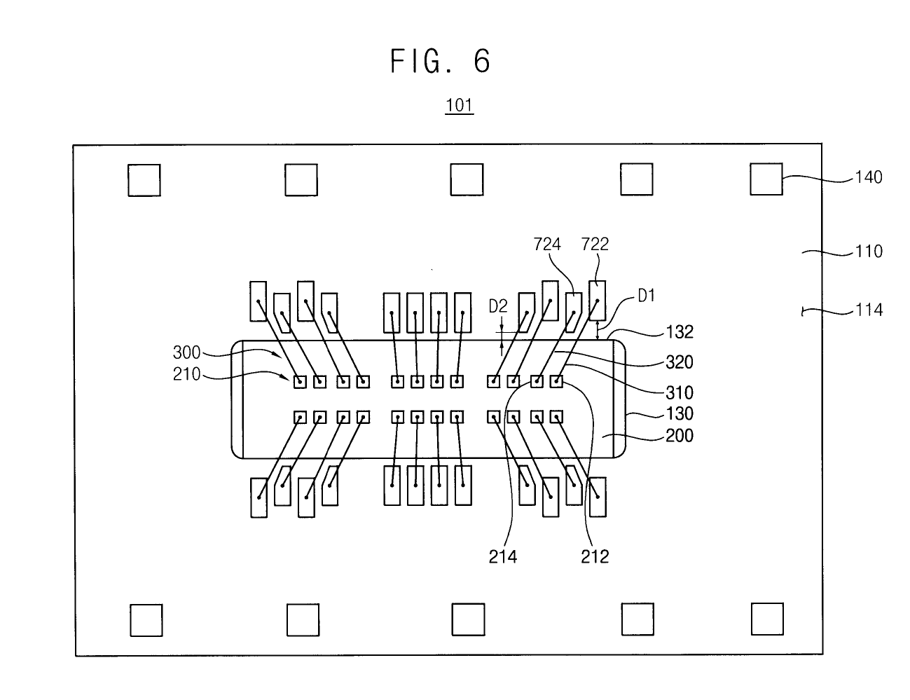

FIG. 5 is a plan view illustrating bonding pads of a semiconductor package in accordance with an exemplary embodiment. The semiconductor package of the exemplary embodiment is substantially the same as the exemplary embodiment of FIG. 1 except for the shapes of certain bonding pads. Thus, the same reference numerals will be used to refer to the same or like elements as those described in the embodiment of FIG. 1 and any further repetitive explanation concerning the above elements will be omitted.

Referring to FIG. 5, in an exemplary embodiment, end portions 622 of bonding pads 620 may have inclined side portions of various angles θL corresponding to drawn angles θW of bonding wires 300. The drawn angle θW of the bonding wire 300 with respect to a side portion 132 of a window 130 may be determined based on an offset arrangement of the chip pad with respect to the imaginary longitudinal line extending through the bonding pad, a distance between the bonding pad and the chip pad, and the like.

In an exemplary embodiment, the end portion 622 of the bonding pad 620 may have a trapezoidal shape. It should be understood that the end portion 622 of the bonding pad 620 may have various shapes as needed, such as trapezoid, semicircle, and the like, in order to avoid interference with an adjacent bonding wire.

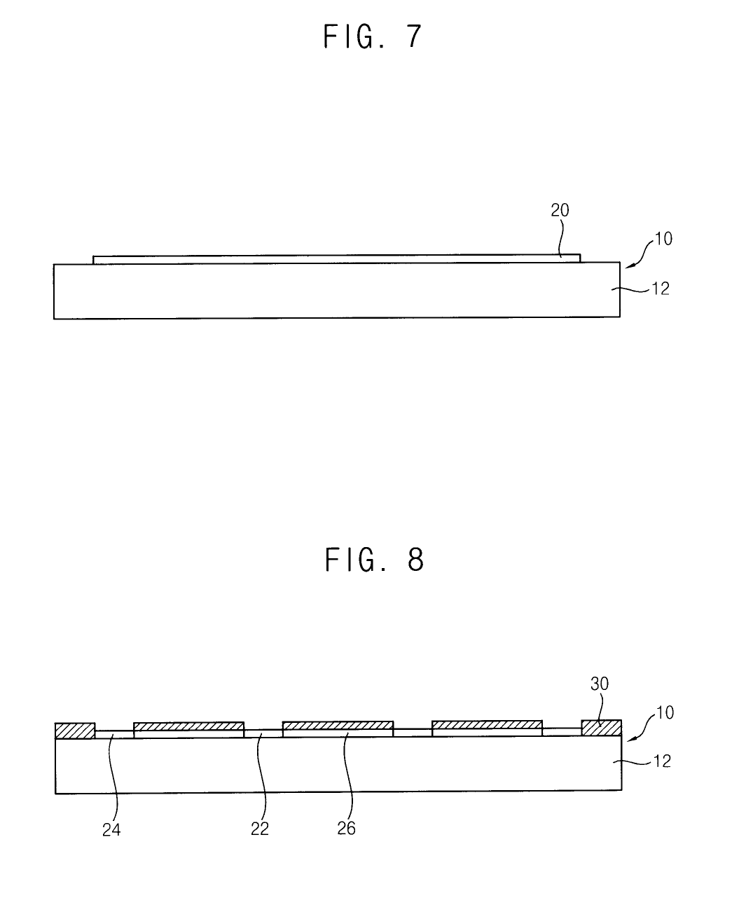

FIG. 6 is a plan view illustrating a semiconductor package in accordance with an exemplary embodiment. The semiconductor package of the present exemplary embodiment is substantially the same as in the exemplary embodiment of FIG. 1 except for the shapes and locations of certain bonding pads. Thus, the same reference numerals will be used to refer to the same or like elements as those described in the embodiment of FIG. 1 and any further repetitive explanation concerning the above elements will be omitted.

Referring to FIG. 6, a semiconductor package 101 according to an exemplary embodiment includes a substrate 110, a semiconductor chip 200, a first bonding pad 722, a second bonding pad 724 and bonding wires 300.

The substrate 110 has a first face (not shown in FIG. 6) and a second face 114 opposite to the first face. The semiconductor chip is adhered to the first face. A window 130 is formed in the middle region of the substrate 110. The window 130 is formed to penetrate the substrate 110.

The semiconductor chip 200 is adhered to the first face of the substrate 110 such that the semiconductor chip 200 is exposed through the window 130. The first bonding pad 722 is arranged on the second face 114 of the substrate along a side portion 132 of the window 130. The second bonding pad 724 is arranged adjacent to the first bonding pad 724 on the second face 114 of the substrate.

The second bonding pad 724 includes an end portion having an inclined side portion. The inclined side portion of the end portion extends at a predetermined angle with respect to the side portion 132 of the window 130.

The first bonding wire 310 is drawn from a first chip pad 212 through the window 130 to be connected to the first bonding pad 722. The first bonding wire 310 is connected to the first bonding pad 722 at a predetermined angle with respect to the side portion 132 of the window 130 corresponding to the inclined side portion of the second bonding pad 724 to avoid an overlap with the second bonding pad 724.

In an exemplary embodiment, a plurality of the first and second bonding pads 722, 724 may be arranged to alternate with each other. Also, in an exemplary embodiment, the first bonding pad 722 may be arranged to be more further from the side portion 132 of the window 130 than the second bonding pad 724 is from the side portion 132.

The first bonding pad 722 may be spaced apart from the side portion 132 of the window 130 by a first distance D1. The second bonding pad 724 may be spaced apart from the side portion 132 of the window 130 by a second distance D2 smaller than the first distance D1.

In an exemplary embodiment, the first chip pad 212 may be connected by the first bonding wire 310 to the first bonding pad 722 that is relatively more distant from the side portion 132 of the window 130. The second chip pad 214 may be connected by the second bonding wire 320 to the second bonding pad 724 that is relatively closer to the side portion 132 of the window 130. Accordingly, the first bonding wire 722 may be longer than the second bonding wire 724.

The end portion of the second bonding pad 724 has an inclined side portion of a predetermined angle with respect to the side portion 132 of the window 130 corresponding to the drawn angle of the first bonding wire 310. Accordingly, the first bonding wire 310 having a relatively greater length may be connected to the first bonding pad 722 without overlapping the second bonding pad 724.

Hereinafter, a method of manufacturing a wiring substrate for a semiconductor chip in accordance with an exemplary embodiment will be explained.

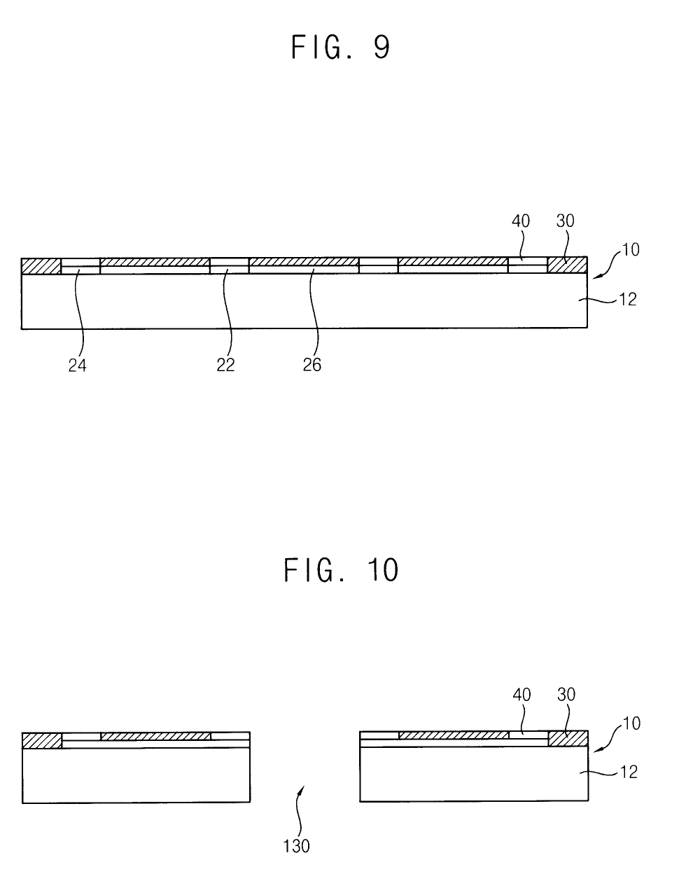

FIGS. 7 to 10 are cross-sectional views illustrating a method of manufacturing the wiring substrate for a semiconductor chip of FIG. 1.

Referring to FIG. 7, a copper clad laminate 10 having an insulation layer 12 and a copper foil (not illustrated) formed on the insulation layer 12 is prepared. The copper clad laminate 10 may have a multi-layered structure such as two layers, four layers, six layers, eight layers, etc. The copper clad laminate 10 may include a circuit pattern and via-holes formed therein according to the purpose of use and the application thereof.

Then, the copper foil is patterned to form a circuit pattern 20 including a bonding pad portion, a solder ball pad portion and a plating lead line. For example, the circuit pattern 20 may be formed by a photolithography process using dry films and liquid photosensitive materials.

In an exemplary embodiment, the bonding pad portion connected to the plating lead line of the circuit pattern 20 may be patterned to form an end portion having an inclined angle with respect to a side portion of a window to be formed by a following process.

Referring to FIG. 8, a solder resist pattern 30 is formed on the copper clad laminate 10. The solder resist pattern 30 exposes the bonding pad portion 22 and the solder ball pad portion 24. Accordingly, the plating lead line 26 is covered with the solder resist pattern 30, and the bonding pad portion 22 and the solder ball pad portion 24 are exposed by the solder resist pattern 30.

Referring to FIG. 9, a plating layer 40 is formed using the plating lead line 26 on the bonding pad portion 22 and the solder ball pad portion 24 exposed by the solder resist pattern 30.

In an exemplary embodiment, the plating layer 40 may include Ni/Au. The plating layer 40 may be formed by an electroplating process.

Referring to FIG. 10, after the plating lead line 26 and the solder resist pattern 30 covering the plating lead line 26 are removed, a window 130 is formed in the middle region of the copper clad laminate 10. For example, the middle region of the copper clad laminate 10 is partially removed using a router bit to form the window 130.

Alternatively, when the window 130 is formed, the plating lead line 26 and the solder resist pattern 30 covering the plating lead line 26 may be removed together using the router bit.

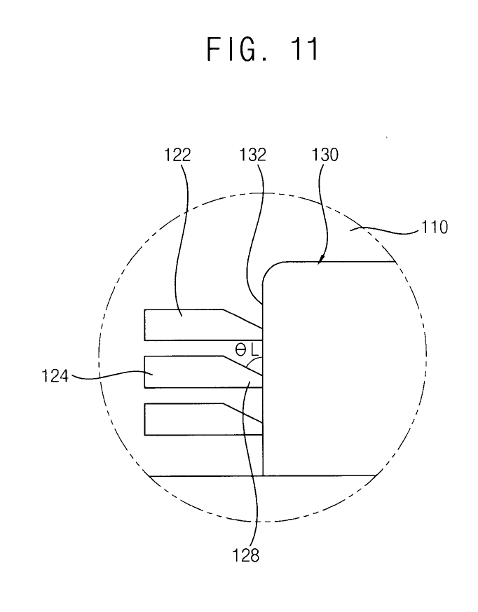

FIG. 11 is an enlarged view illustrating the wiring substrate for the semiconductor chip of FIG. 10.

Referring to FIG. 11, the wiring substrate for a semiconductor chip according to an exemplary embodiment includes first and second bonding pads 122, 124 formed on a substrate 110. The first and second bonding pads 122, 124 are arranged along a side portion 132 of a window 130.

The second bonding pad 124 includes an end portion 128 having an inclined side portion of a predetermined angle θL with respect to the side portion 132 of the window 130 corresponding to a drawn angle of a bonding wire that would be connected to the first bonding pad 122, to avoid an overlap with the bonding wire.

As mentioned above, a wiring substrate for a semiconductor chip in accordance with exemplary embodiments includes adjacent first and second bonding pads on a substrate, the second bonding pad includes an end portion having an inclined side portion of a predetermined angle with respect to a side portion of the window, the inclined side portion corresponding to the drawn angle of a bonding wire connected to the first bonding pad, to avoid an overlap of the second bonding pad with the first bonding wire.

Accordingly, even though the first and second bonding pads are spaced apart from each other by a relatively small distance and the bonding wire is connected to the first bonding pad at a predetermined angle with respect to the side portion of the window, the second bonding pad may be prevented from overlapping the first bonding wire. Thus, a contact failure between the second bonding pad and the bonding wire may be prevented.

The foregoing is illustrative of exemplary embodiments and is not to be construed as limiting thereof. Although practical exemplary embodiments have been disclosed, those skilled in the art will readily appreciate that many modifications are possible to the exemplary embodiments Accordingly, the disclosed exemplary embodiments, all such modifications to the disclosed exemplary embodiments, as well as other exemplary embodiments, are intended to be included within the scope of the appended claims.

What is claimed is:

1. A wiring substrate for a semiconductor chip, comprising:
a substrate having a first face and a second face opposite to the first face, the substrate having a window from the first face to the second face that exposes chip pads of a semiconductor chip adherable to the first face;
a first bonding pad arranged on the second face along a side portion of the window, the first bonding pad connected to a bonding wire that is drawn from the chip pad through the window at a predetermined angle with respect to the side portion of the window; and
a second bonding pad adjacent to the first bonding pad on the second face, the second bonding pad including an end portion having an inclined side portion of a predetermined angle with respect to the side portion of the window corresponding to a drawn angle of the bonding wire for avoiding an overlap of the second bonding pad with the first bonding wire.

2. The wiring substrate of claim 1, wherein the inclined side portion of the end portion of the second bonding pad extends at substantially the same angle as the drawn angle of the bonding wire.

3. The wiring substrate of claim 1, wherein the end portion of the second bonding pad has an angle of the inclined side portion that ranges from about 10° to about 50° from the side portion of the window.

4. The wiring substrate of claim 1, wherein the width of the end portion of the second bonding pad decreases gradually toward the window.

5. The wiring substrate of claim 1, wherein the second bonding pad comprises a pad body connected to a second bonding wire, the pad body having a first width and the end portion of the second bonding pad having a second width smaller than the first width.

6. The wiring substrate of claim 1, wherein the pad body of the second bonding pad has a modified rectangular shape characterized by the end portion of the second bonding pad having a trapezoidal shape.

7. The wiring substrate of claim 1, wherein the first and second bonding pads extend substantially perpendicular to the side portion of the window.

8. The wiring substrate of claim 1, wherein a plurality of the first and second bonding pads is arranged to alternate with one another, a first bonding pad being spaced further from the side portion of the window than a second bonding pad spaced from the side portion.

9. A semiconductor package, comprising:
a substrate having a first face and a second face opposite to the first face and having a window from the first face to the second face;
a semiconductor chip adhered to the first face of the substrate and having semiconductor chip pads exposed through the window;
a first bonding pad arranged on the second face along a side portion of the window;
a second bonding pad adjacent to the first bonding pad on the second face, the second bonding pad including an end portion having an inclined side portion of a predetermined angle with respect to the side portion of the window; and
a bonding wire drawn from the chip pad through the window and connected to the first bonding pad at a predetermined angle with respect to the side portion of the window corresponding to the inclined side portion of the second bonding pad for avoiding an overlap of the second bonding pad with the bonding wire.

10. The semiconductor package of claim 9, wherein the second bonding pad comprises a pad body connected to a second bonding wire, the pad body having a first width, the end portion of the second bonding pad having a second width smaller than the first width, and the chip pad of the semiconductor chip having a third width smaller than the first width.

11. The semiconductor package of claim 9, wherein the inclined side portion of the end portion of the second bonding pad extends at substantially the same angle as a drawn angle of the bonding wire.

12. The semiconductor package of claim 9, wherein the end portion of the second bonding pad has an angle of the inclined side portion ranging from about 10° to about 50° from the side portion of the window.

13. The semiconductor package of claim 1, wherein the width of the end portion of the second bonding pad decreases gradually toward the window.

14. The semiconductor package of claim 9, wherein the second bonding pad comprises a pad body connected to a second bonding wire, the pad body of the second bonding pad having a modified rectangular shape characterized by the end portion of the second bonding pad having a trapezoidal shape.

15. The semiconductor package of claim 9, wherein the first and second bonding pads extends substantially perpendicular to the side portion of the window.

16. The semiconductor package of claim 9, wherein a plurality of the first and second bonding pads is arranged to alternate with one another, and the first bonding pad is arranged more further from the side portion of the window than the second bonding pad.

17. A wiring interconnection apparatus for a semiconductor chip that adheres to a substrate, the substrate having a window from a substrate adhering surface to a bonding pad surface, the wiring interconnection apparatus comprising:
a plurality of chip pads arranged on a surface of the semiconductor chip that adheres to the substrate adhering surface;
a plurality of bonding pads arranged substantially parallel on the bonding pad substrate surface; and
a plurality of bonding wires, each bonding wire passing through the window and coupling a respective chip pad and bonding pad,
wherein each bonding pad is shaped such that a bonding wire of an adjacent bonding pad does not overlap the each bonding pad.

18. The wiring interconnection apparatus of claim 17, wherein at least one bonding pad has an inclined edge substantially parallel to a bonding wire of an adjacent bonding pad.

19. The wiring interconnection apparatus of claim 17, wherein the bonding pads are substantially perpendicular to a side portion of the window.

20. The wiring interconnection apparatus of claim 19, wherein at least one of the bonding wires is oblique to the side portion of the window.
